(19) United States
(12) Patent Application Publication
(10) Pub. No.: US 2023/0051462 A1
(43) Pub. Date: Feb. 16, 2023

(54) DIFFERENTIAL AMPLIFIER COMMON MODE VOLTAGE

(71) Applicant: TEXAS INSTRUMENTS INCORPORATED, Dallas, TX (US)

(72) Inventor: Joseph Alan SANKMAN, Dallas, TX (US)

(21) Appl. No.: 17/828,167

(22) Filed: May 31, 2022

Related U.S. Application Data
(60) Provisional application No. 63/232,635, filed on Aug. 13, 2021.

(51) Int. Cl. H03F 3/45; H03M 1/12

(52) U.S. Cl. CPC H03F 3/45273; H03F 3/4508; H03M 1/12; H03F 2203/45; H03F 2200/69

(57) ABSTRACT

An amplifier includes a first stage and a second stage. The first stage includes a first output, and a second output. The second stage includes a first transistor, a second transistor, and a common-mode circuit. The first transistor includes a drain coupled to the first output of the first stage. The second transistor includes a drain coupled to the second output of the first stage. The common-mode circuit includes a reversible current mirror circuit coupled to the drain of the first transistor and the drain of the second transistor.

### CROSS-REFERENCE TO RELATED APPLICATIONS

This application claims priority to U.S. Provisional Application No. 63/232,635, filed Aug. 13, 2021, entitled “Low IQ Reversible Current Mirror for Common-Mode Setting,” which is hereby incorporated by reference.

### BACKGROUND

Amplifiers are used in a wide variety of applications. A fully differential amplifier is type of amplifier that amplifies differential input signals and outputs the amplified signals as differential output signals. In fully differential amplifiers, a common-mode voltage is provided at the amplifier's differential outputs. The amplifier may include a common mode feedback circuit that controls the common mode voltage based on feedback from the amplifier's differential outputs and a predetermined reference voltage.

### SUMMARY

In one example, an amplifier includes a first stage and a second stage. The includes a first output, and a second output. The second stage includes a first transistor, a second transistor, and a common-mode circuit. The first transistor includes a drain coupled to the first output of the first stage. The second transistor includes a drain coupled to the second output of the first stage. The common-mode circuit includes a reversible current mirror circuit coupled to the drain of the first transistor and the drain of the second transistor.

In another example, an amplifier includes a first stage and a second stage. The first stage includes differential inputs and differential outputs. The second stage includes a single-ended output, a first transistor, a second transistor, a third transistor, a fourth transistor, and a common-mode circuit. The single-ended output is coupled to one of the differential inputs. The first transistor is configured to source current to the single-ended output. The second transistor is configured to sink current from the single-ended output. The third transistor includes a drain coupled to a first of the differential outputs, and is configured to drive the first transistor. The fourth transistor includes a drain coupled to a second of the differential outputs, and is configured to drive the second transistor. The common-mode circuit is coupled to the drain of the third transistor, and the drain of the fourth transistor. The common-mode circuit includes a reversible current mirror circuit configured to generate a common mode voltage at the drain of the third transistor and the drain of the fourth transistor.

In a further example, an analog-to-digital conversion circuit includes an analog-to-digital converter and a voltage reference coupled to the analog-to-digital converter. The voltage reference includes a reference voltage circuit and an amplifier. The amplifier is coupled between the reference voltage circuit and the analog-to-digital converter. The amplifier includes a first stage and a second stage. The first stage includes differential outputs and differential inputs. A first of the differential inputs is coupled to the reference voltage circuit. The second stage includes a single-ended output, a first transistor, a second transistor, a third transistor, a fourth transistor, and a common-mode circuit. The single-ended output is coupled to a second of the differential inputs. The first transistor is configured to source current to the single-ended output. The second transistor is configured to sink current from the single-ended output. The third transistor includes a drain coupled to a first of the differential outputs, and is configured to drive the first transistor. The fourth transistor includes a drain coupled to a second of the differential outputs, and is configured to drive the second transistor. The common-mode circuit is coupled to the drain of the third transistor and the drain of the fourth transistor. The common-mode circuit includes a reversible current mirror circuit configured to generate a common mode voltage at the drain of the third transistor and the drain of the fourth transistor.

### BRIEF DESCRIPTION OF THE DRAWINGS

FIG. 1 is a block diagram of an example analog-to-digital conversion circuit.

FIG. 2 is block diagram of an example voltage reference circuit suitable for use in the analog-to-digital conversion circuit of FIG. 1.

FIG. 3 is a schematic diagram of an example amplifier circuit.

FIG. 4 is a schematic diagram of another example amplifier circuit.

FIGS. 5A and 5B illustrate operation of the common-mode circuit of FIG. 4.

FIG. 6 is a graph of example output of the amplifier of FIG. 3 over a range of load currents.

### DETAILED DESCRIPTION

Analog-to-digital converters (ADCs) are used in a wide variety of applications (e.g., medical devices, flow and temperature metering devices, wireless sensors, etc.). ADC circuitry may include a voltage reference circuitry that generates a reference voltage for use by the ADC. In many applications, circuitry, including the ADC and related circuitry is battery powered. It is desirable to reduce the power used by ADC circuitry to increase battery life. For example, an ADC may be duty cycled to reduce power use. In such systems, the voltage reference circuitry may be always-on to enable faster start-up. Therefore, low quiescent current, low-noise voltage reference circuitry is desirable.

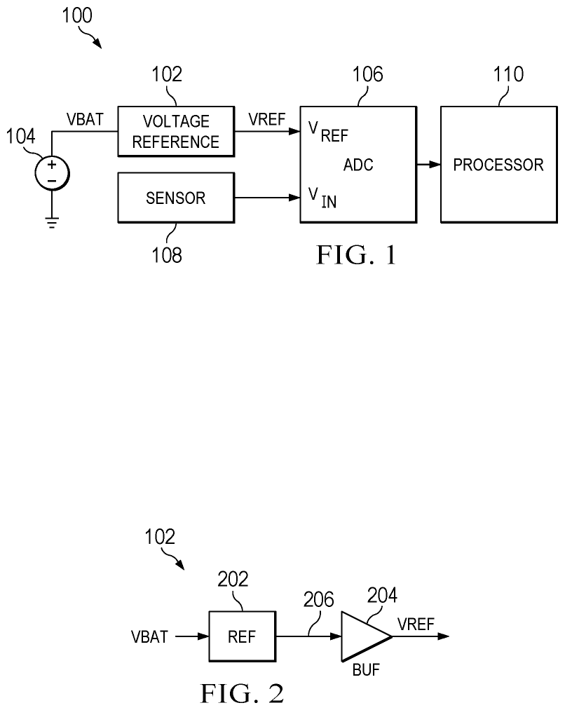

FIG. 1 is a block diagram of an example analog-to-digital conversion circuit 100. The analog-to-digital conversion circuit 100 includes a voltage reference circuit 102, a voltage source 104, an ADC 106, a sensor 108, and a processor 110. The voltage reference circuit 102 is coupled to the voltage source 104, and outputs a regulated reference voltage for use by the ADC 106. The voltage source 104 may be a battery or other power supply that provides a voltage (VBAT) for powering the voltage reference circuit 102 and other circuitry of the analog-to-digital conversion circuit 100.

The ADC 106 is coupled to the voltage reference circuit 102 for receipt of the reference voltage generated by the voltage reference circuit 102. The ADC 106 applies the reference voltage to digitize a measurement signal received from the sensor 108. The sensor 108 is coupled to the ADC 106, and provides a measurement signal to the ADC 106. The sensor 108 may be, for example, a temperature sensor, a humidity sensor, a voltage sensor, a current sensor, a flow sensor, or any other sensor that produces a measurement signal. The ADC 106 may be configured to implement any of a variety of digitization techniques to convert the measurement signal to a digital value. For example, the ADC 106 may be a successive approximation register ADC, a delta-sigma ADC, a dual slope, ADC, a pipelined ADC, a FLASH ADC, or other type of ADC.

The ADC 106 is coupled to the processor 110. The ADC 106 provides digitized values of the measurement signal to the processor 110 for processing. The processor 110 may be a microcontroller, a general-purpose microprocessor, a digital signal processor, or other digital circuit configured to process digital measurement values generated by the ADC 106.

FIG. 2 is block diagram of an example voltage reference circuit 102 suitable for use in the analog-to-digital conversion circuit 100. The voltage reference circuit 102 includes a reference voltage circuit 202 and an amplifier 204 (a buffer amplifier). The reference voltage circuit 202 is coupled to the voltage source 104 for reception of VBAT. The reference voltage circuit 202 may include a bandgap circuit or other voltage regulation circuit to generate an unbuffered reference voltage 206. The amplifier 204 is coupled to the reference voltage circuit 202. The amplifier 204 receives the unbuffered reference voltage 206 generated by the reference voltage circuit 202, and buffers the unbuffered reference voltage 206 for use by the ADC 106. The amplifier 204 may include a class AB output stage.

In the voltage reference circuit 102, a large portion of the quiescent current (e.g., as much as possible) may be allocated to the reference voltage circuit 202 to reduce thermal noise. Consequently, the quiescent current available to the amplifier 204 is reduced, and proper biasing of the amplifier 204 is challenging.

If the output stage of the amplifier 204 is class AB, the circuitry may be more complex than that of a standard low drop out class A output stage. For example, a differential folded cascode topology may be used to meet low input voltage (e.g., 1.7 volts) specifications, and maintain operation at high (e.g., 125 degrees Celsius) temperatures. In the differential folded cascode topology, one side of the folded cascode drives a sourcing output transistor, and the other side drives a sinking output transistor.

The common-mode voltage applied to the differential folded cascode sets the quiescent current of the amplifier 204 with no load, and biases the cascode transistors to the desired operating region (saturation). Use of common-mode feedback (CMFB) amplifier circuitry to set the common-mode voltage is problematic due to stability issues associated with low quiescent current operation. A CMFB amplifier may have less unity gain bandwidth (UGBW) than the amplifier 204 (which is not possible under no-load conditions), or the CMFB have higher UGBW than the amplifier 204 (which is not possible due low quiescent current requirements). Otherwise, the amplifier 204 may become unstable when the CMFB amplifier gain crosses 0 dB over frequency (reaches unity gain bandwidth frequency). Addition of a resister across the outputs of the differential folded cascode is ineffective because the differential voltages undergo large swings (due to swings in load current (e.g., no-load to heavy load).

The common-mode circuitry included in the 204 employs low gain (unity gain, or <20 dB gain) to set the common-mode voltage in the differential folded cascode, which avoids stability issues and circuit complexity. The amplifier 204 includes a reversible current mirror circuit that sets the common-mode voltage for the differential folded cascode. The low quiescent current requirement of the reversible current mirror circuitry is more compact than the CMFB amplifier circuitry, and allows the quiescent current provided to the reference voltage circuit 202 to be increased, which reduces noise on the reference voltage.

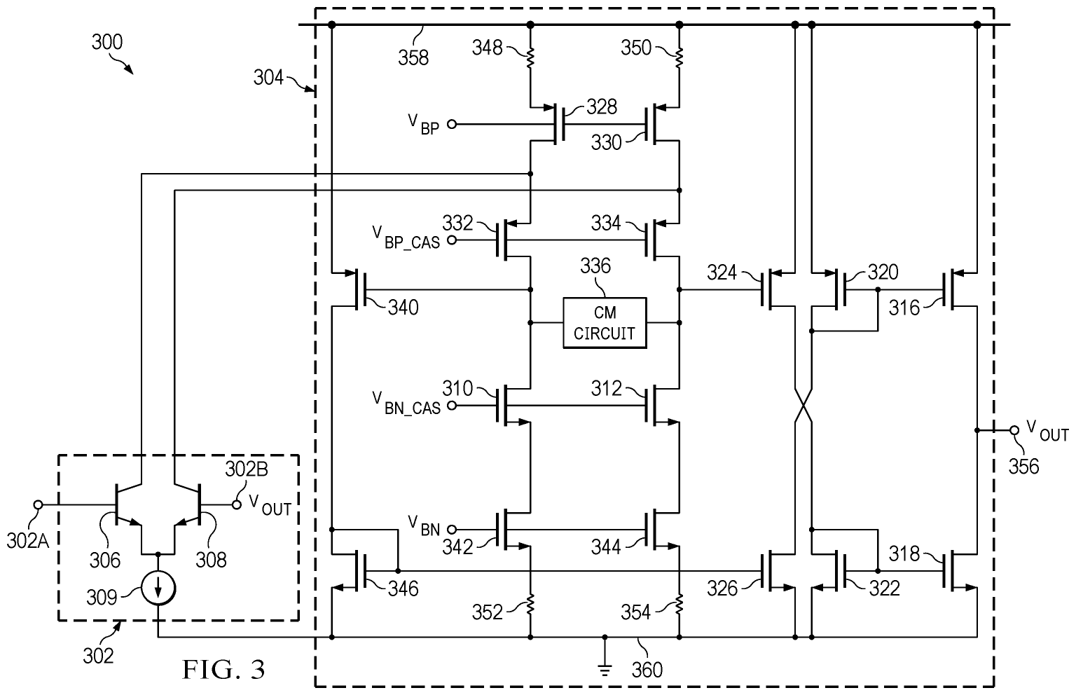

FIG. 3 is a schematic diagram of an example amplifier 300, that includes a common-mode circuit. The amplifier 300 is an implementation of the amplifier 204. The amplifier 300 includes an input stage 302 and an output stage 304. The output stage 304 is coupled to the input stage 302. The input stage 302 includes differential inputs (input 302A and input 302B) and differential outputs. The transistor 306 and the transistor 308 (input transistors) are connected as a differential pair. The transistor 306 and the transistor 308 may be NPN bipolar junction transistors. The base of the transistor 306 is coupled to the input 302A, and the base of the transistor 308 is coupled to the input 302B. The emitter of the transistor 306 is coupled to the emitter of the transistor 308 and to a tail current source 309. A first output of the input stage 302 is provided at the collector of the transistor 306, and a second output of the input stage 302 is provided at the collector of the transistor 308.

The output stage 304 is a differential cascode circuit, and includes high-side circuitry and low-side circuitry. The high-side circuitry includes transistor 316, transistor 320, transistor 326, transistor 346, transistor 328, transistor 332, transistor 340, transistor 342, cascode transistor 310, resistor 348, and resistor 352. The transistor 316, the transistor 320, the transistor 332, the transistor 340, and the transistor 328 may be p-channel field effect transistors (PFETs). The transistor 326, the transistor 346, the transistor 342, and the cascode transistor 310 may be p-channel FETs (NFETs). The transistor 316 sources current to the output terminal 356 based on a control signal provided at the drain of the cascode transistor 310, through the transistor 340, the transistor 346, the transistor 326, and the transistor 320. The source of the transistor 328 is coupled to a power supply terminal 358 via the resistor 348. A drain of the transistor 328 is coupled to a source of the transistor 332 and the collector of the transistor 306. A gate of the transistor 328 is coupled to a gate of the transistor 332 and a PFET bias voltage source (not shown). A drain of the transistor 332 is coupled to a drain of the cascode transistor 310 and a gate of the transistor 340. A source of the cascode transistor 310 is coupled to a drain of the transistor 342. A gate of the cascode transistor 310 is coupled to a cascode bias voltage source (not shown). A source of the transistor 342 is coupled to a ground terminal 360 via the resistor 352. A gate of the transistor 342 is coupled to an NFET bias voltage source (not shown).

A source of the transistor 340 is coupled to the power supply terminal 358, and a drain of the transistor 340 is coupled to a drain and gate of the transistor 346. A source of the transistor 346 is coupled the ground terminal 360. The gate of the transistor 346 is coupled to a gate of the transistor 326 to form a current mirror. A source of the transistor 326 is coupled to the ground terminal 360. A drain of the transistor 326 is coupled to a drain and gate of the transistor 320. A source of the transistor 320 is coupled to the power supply terminal 358. A gate of the transistor 320 is coupled to a gate of the transistor 316 to form a current mirror. A source of the transistor 316 is coupled to the power supply terminal 358, and a drain of the transistor 316 is coupled to the output terminal 356.

The low-side circuitry includes transistor 318, transistor 322, transistor 324, transistor 330, transistor 334, transistor 344, cascode transistor 312, resistor 350, and resistor 354. The transistor 318, the transistor 322, the cascode transistor 312, and the transistor 344 may be NFETs. The transistor 324, the transistor 334, and the transistor 340 may be PFETs. The transistor 318 sinks current from the output terminal 356 based on a control signal provided at the drain of the cascode transistor 312, through the transistor 324 and the transistor 322. The source of the transistor 330 is coupled to the power supply terminal 358 via the resistor 350. A drain of the transistor 330 is coupled to a source of the transistor 334 and the collector of the transistor 308. A gate of the transistor 330 is coupled to a gate of the transistor 334 and a gate of the transistor 328. A drain of the transistor 334 is coupled to a drain of the cascode transistor 312 and a gate of the transistor 324. A source of the cascode transistor 312 is coupled to a drain of the transistor 344. A gate of the cascode transistor 312 is coupled to the gate of the cascode transistor 310. A source of the transistor 344 is coupled to the ground terminal 360 via the resistor 354. A gate of the transistor 344 is coupled to the gate of the transistor 342.

A source of the transistor 324 is coupled to the power supply terminal 358, and a drain of the transistor 324 is coupled to a drain and gate of the transistor 322. A source of the transistor 322 is coupled to the ground terminal 360. A gate of the transistor 322 is coupled to a gate of the transistor 318 to form a current mirror. A source of the transistor 318 is coupled to the ground terminal 360, and a drain of the transistor 318 is coupled to the output terminal 356.

A common-mode circuit 336 is coupled to the drain of the cascode transistor 310 and the drain of the cascode transistor 312. The common-mode circuit 336 sets the DC voltage at the drain of the cascode transistor 310 and the drain of the cascode transistor 312 to a common predetermined value.

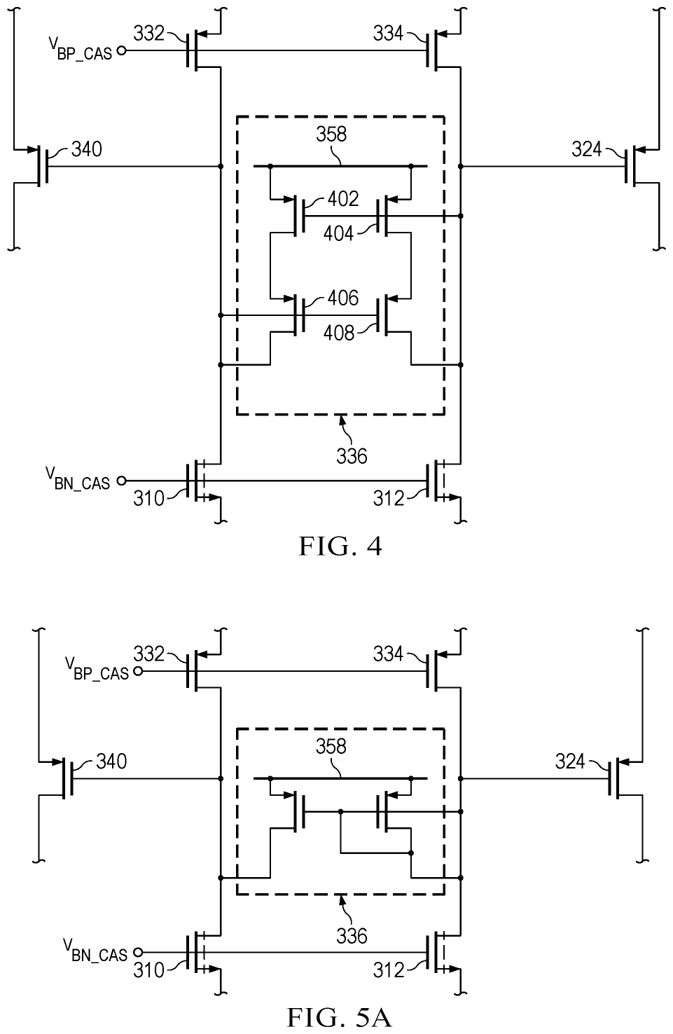

FIG. 4 is a schematic diagram of an example of the common-mode circuit 336. The common-mode circuit 336 includes the transistor 402, the transistor 404, the transistor 406, and the transistor 408 connected to form a reversible current mirror circuit. The transistor 402, the transistor 404, the transistor 406, and the transistor 408 may be PFETs. The reversible current mirror circuit is implemented using two stacked current mirror circuits, where one of the stacked current mirror circuits is controlled by each side (positive or negative) of the differential cascode circuit.

A source of the transistor 402 and a source of the transistor 404 are coupled to the power supply terminal 358. A gate of the transistor 402 and a gate of the transistor 404 are coupled to the drain of the cascode transistor 312. A gate of the transistor 406 and a gate of the transistor 408 are coupled to the drain of the cascode transistor 310. A source of the transistor 406 is coupled to a drain of the transistor 402. A source of the transistor 408 is coupled to a drain of the transistor 404. A drain of the transistor 406 is coupled to the drain of the cascode transistor 310. A drain of the transistor 408 is coupled to the drain of the cascode transistor 312. The current flowing in the 336 is set by the top and bottom current sources of the output stage 304 (the transistors 328, 330, 342, 344).

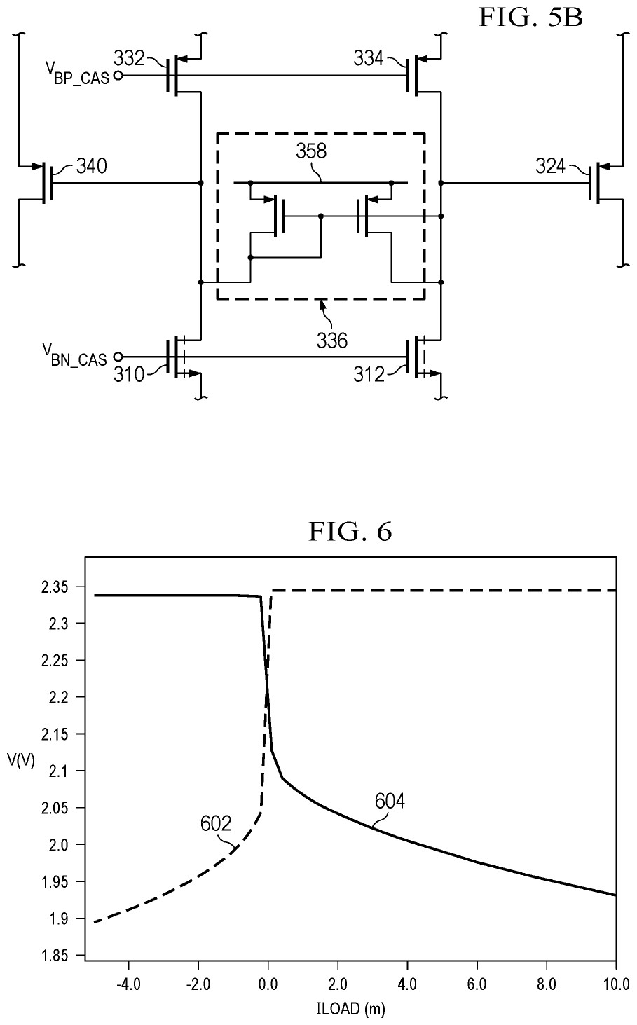

FIGS. 5A and 5B illustrate operation of the common-mode circuit 336. The current mirror circuitry of the common-mode circuit 336 is reversed (orientation of the current mirror provided by the common-mode circuit 336 is reversed) based on the whether the load current at the output terminal 356 (controlled via the transistor 340 and the transistor 324) is positive or negative. The folded cascode outputs are differential, and swing high or low responsive to negative or positive load current. The differential outputs of the folded cascode swing in a large signal sense—the outputs are not linearly differential because the swing of the load currents may be asymmetric (e.g., −5 ma to +10 ma).

FIG. 5A shows that when the gate-source voltage (VGs) of the transistor 340 is large, and the VGS of the transistor 324 is small, the common-mode circuit 336 operates as a current mirror circuit with a diode-connected transistor coupled to the drain of the cascode transistor 312, and a mirror transistor coupled to the drain of the cascode transistor 310. FIG. 5B shows that when the VGS of the transistor 324 is large, and the VGS of the transistor 340 is small, the common-mode circuit 336 operates as a current mirror circuit with a diode-connected transistor coupled to the drain of the cascode transistor 310, and a mirror transistor coupled to the drain of the cascode transistor 312. Operation of the common-mode circuit 336 may also be described as making the differential folded cascode look like a single-ended output folded cascode, with the output changing sides depending on the orientation of the current mirror.

FIG. 6 is a graph of example output of the amplifier 300 over a range of load currents. In FIG. 6, the curve 602 represents the voltage at the drain of the cascode transistor 312, and the curve 604 represents the voltage at the drain of the cascode transistor 310. With negative load current, the common-mode circuit 336 operates as shown in FIG. 5A. Accordingly, the transistor 340 acts as a current mirror, while the transistor 324 operates as an output to control the transistor 318. With positive load current, the common-mode circuit 336 operates as shown in FIG. 5B. Accordingly, the transistor 324 acts as a current mirror, while the transistor 340 operates as an output to control the transistor 316.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead. For example, a p-channel field effect transistor (“PFET”) may be used in place of an n-channel field effect transistor (“NFET”) with little or no changes to the circuit. Furthermore, other types of transistors may be used (such as bipolar junction transistors (BJTs)).

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter.

The same reference number is used in the drawings for the same or similar (either by function and/or structure) features.

Modifications are possible in the described embodiments, and other embodiments are possible, within the scope of the claims.

What is claimed is:

1. An amplifier, comprising:
a first stage including a first output, and a second output; and
a second stage, including:
a first transistor including:
a drain coupled to the first output of the first stage;
a second transistor including:
a drain coupled to the second output of the first stage; and
a common-mode circuit coupled to the drain of the first transistor and the drain of the second transistor, the common-mode circuit including a reversible current mirror circuit.

2. The amplifier of claim 1, wherein the reversible current mirror circuit includes two stacked current mirror circuits.

3. The amplifier of claim 1, wherein the reversible current mirror circuit includes:
a third transistor including:
a source coupled to a power supply terminal; and
a gate coupled to the drain of the first transistor.

4. The amplifier of claim 3, wherein the reversible current mirror circuit includes:
a fourth transistor including:
a source coupled to the power supply terminal; and
a gate coupled to the drain of the first transistor.

5. The amplifier of claim 4, wherein:
the third transistor includes a drain; and
the reversible current mirror circuit includes:
a fifth transistor including:
a source coupled to the drain of the third transistor;
a gate coupled to the drain of the second transistor; and
a drain coupled to the drain of the first transistor.

6. The amplifier of claim 5, wherein:
the fourth transistor includes a drain; and
the reversible current mirror circuit includes:
a sixth transistor including:
a source coupled to the drain of the fourth transistor;
a gate coupled to the drain of the second transistor; and
a drain coupled to the drain of the second transistor.

7. The amplifier of claim 1, further comprising:
an output terminal;
a third transistor including:
a gate coupled to the drain of the first transistor;
a drain coupled to the output terminal; and
a source coupled a power supply terminal; and
a fourth transistor including:
a gate coupled to the drain of the second transistor;
a drain coupled to the output terminal; and
a source coupled to a ground terminal.

8. The amplifier of claim 1, wherein the first stage further comprises:
a third transistor including:
a collector coupled to the drain of the first transistor; and
an emitter; and
a fourth transistor including:
a collector coupled to the drain of the second transistor; and
an emitter coupled to the emitter of the third transistor.

9. An amplifier, comprising:
a first stage including differential inputs and differential outputs;
a second stage including:
a single-ended output coupled to one of the differential inputs;
a first transistor configured to source current to the single-ended output;
a second transistor configured to sink current from the single-ended output;
a third transistor including a drain coupled to a first of the differential outputs, and configured to drive the first transistor;
a fourth transistor including a drain coupled to a second of the differential outputs, and configured to drive the second transistor; and
a common-mode circuit coupled to the drain of the third transistor and the drain of the fourth transistor, the common-mode circuit including a reversible current mirror circuit configured to generate a common mode voltage at the drain of the third transistor and the drain of the fourth transistor.

10. The amplifier of claim 9, wherein the reversible current mirror circuit includes two stacked current mirror circuits.

11. The amplifier of claim 10, wherein a first of the stacked current mirror circuits is controlled by a voltage at the drain of the third transistor, and a second of the stacked current mirror circuits is controlled by a voltage at the drain of the fourth transistor.

12. The amplifier of claim 10, wherein a first of the stacked current mirror circuits is activated responsive to a positive load current, and a second of the stacked current mirror circuits is activated responsive to a negative load current.

13. The amplifier of claim 9, wherein the reversible current mirror circuit includes:
a fifth transistor including:
a source coupled to a power supply terminal; and
a gate coupled to the drain of the third transistor; and
a sixth transistor including:
a source coupled to the power supply terminal; and
a gate coupled to the drain of the third transistor.

14. The amplifier of claim 13, wherein:
the fifth transistor includes a drain;
the sixth transistor includes a drain; and
the reversible current mirror circuit includes:
a seventh transistor including:
a source coupled to the drain of the fifth transistor;
a gate coupled to the drain of the fourth transistor; and
a drain coupled to the drain of the third transistor; and
an eighth transistor including:
a source coupled to the drain of the sixth transistor;
a gate coupled to the drain of the fourth transistor; and
a drain coupled to the drain of the fourth transistor.

15. An analog-to-digital conversion circuit, comprising:
an analog-to-digital converter; and
a voltage reference coupled to the analog-to-digital converter, the voltage reference including:
a reference voltage circuit; and
an amplifier coupled between the reference voltage circuit and the analog-to-digital converter, the amplifier including:
a first stage including differential outputs and differential inputs, a first of the differential inputs coupled to the reference voltage circuit; and
a second stage including:
a single-ended output coupled to a second of the differential inputs;
a first transistor configured to source current to the single-ended output;
a second transistor configured to sink current from the single-ended output;
a third transistor including a drain coupled to a first of the differential outputs, and configured to drive the first transistor;
a fourth transistor including a drain coupled to a second of the differential outputs, and configured to drive the second transistor; and
a common-mode circuit coupled to the drain of the third transistor, and the drain of the fourth transistor, the common-mode circuit including a reversible current mirror circuit configured to generate a common mode voltage at the drain of the third transistor and the drain of the fourth transistor.

16. The amplifier of claim 15, wherein the reversible current mirror circuit includes two stacked current mirror circuits.

17. The amplifier of claim 16, wherein a first of the stacked current mirror circuits is controlled by a voltage at the drain of the third transistor, and a second of the stacked current mirror circuits is controlled by a voltage at the drain of the fourth transistor.

18. The amplifier of claim 16, wherein a first of the stacked current mirror circuits is activated responsive to a positive load current, and a second of the stacked current mirror circuits is activated responsive to a negative load current.

19. The amplifier of claim 15, wherein the reversible current mirror circuit includes:
a fifth transistor including:
a drain;
a source coupled to a power supply terminal; and
a gate coupled to the drain of the third transistor; and
a sixth transistor including:
a drain;
a source coupled to the power supply terminal; and
a gate coupled to the drain of the third transistor.

20. The amplifier of claim 19, wherein the reversible current mirror circuit includes:
a seventh transistor including:
a source coupled to the drain of the fifth transistor;
a gate coupled to the drain of the fourth transistor; and
a drain coupled to the drain of the third transistor; and
an eighth transistor including:
a source coupled to the drain of the sixth transistor;
a gate coupled to the drain of the fourth transistor; and
a drain coupled to the drain of the fourth transistor.
